(19) United States
(12) Patent Application Publication
(10) Pub. No.: US 2026/0334232 A1
(43) Pub. Date: Oct. 22, 2026

(54) SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/310,931

(22) Filed: Aug. 27, 2025

(30) Foreign Application Priority Data
Apr. 22, 2025 (KR) 10-2025-0052109

(51) Int. Cl. H10W 42/00; H10W 46/00

(52) U.S. Cl. CPC H10W 42/00; H10W 42/121; H10W 46/00; H10W 46/301; H10W 46/503

(57) ABSTRACT

A semiconductor device may include a substrate having a chip region, a guard ring region disposed around the chip region, and a scribe lane region disposed around the guard ring region, a guard ring disposed in the guard ring region, surrounding the chip region, and including a first horizontal guard portion and a second horizontal guard portion intersecting with the first horizontal guard portion, an alignment key disposed in an alignment region inside the scribe lane region, the alignment key being spaced apart from the first horizontal guard portion in a first direction in which the second horizontal guard portion extends, and a barrier structure disposed between the first horizontal guard portion and the alignment key.

### CROSS-REFERENCES TO RELATED APPLICATION

The present application claims priority under 35 U.S.C. 119(a) to Korean patent application number 10-2025-0052109 filed on Apr. 22, 2025, which is incorporated herein by reference in its entirety.

### BACKGROUND

### 1. Technical Field

Embodiments of the present disclosure relate generally to a semiconductor device.

### 2. Related Art

As semiconductor devices become increasingly more highly integrated, they are often fabricated on a single wafer and then separated through a cutting process such as sawing or dicing.

However, as the integration level of semiconductor devices increases, existing cutting processes face technical challenges. For example, various keys such as alignment keys which are placed in the cutting region through which a cutting line (CL) passes may be cracked or delaminated in the areas near the keys during the cutting process. To ensure the reliability and efficiency of semiconductor manufacturing, further advancements in dicing technology are necessary to address these issues and minimize defects.

### SUMMARY

It is noted that the advantages of the embodiments of the present disclosure may not be limited to those explicitly mentioned herein, and that other advantages not explicitly stated may be understood by those skilled in the art from the detailed description that follows.

Embodiments of the present disclosure may provide an improved method and semiconductor device capable of minimizing defects generated during the cutting process.

Some embodiments of the present disclosure provide a semiconductor device including a substrate including a chip region, a guard ring region disposed around the chip region, and a scribe lane region disposed around the guard ring region, a guard ring disposed in the guard ring region, surrounding the chip region, and including a first horizontal guard portion and a second horizontal guard portion intersecting with the first horizontal guard portion, an alignment key disposed in an alignment region inside the scribe lane region and spaced apart from the first horizontal guard portion in a first direction in which the second horizontal guard portion extends, and a barrier structure disposed between the first horizontal guard portion and the alignment key.

Some other embodiments of the present disclosure provide a semiconductor device including a substrate including a chip region, a guard ring region disposed around the chip region, and a scribe lane region disposed around the guard ring region, a guard ring disposed in the guard ring region and surrounding the chip region, an alignment key disposed in the scribe lane region and spaced apart from the guard ring in a first direction in which the guard ring extends, and a barrier structure disposed between the guard ring and the alignment key, the barrier structure having a length in a second direction intersecting the first direction, the length being shorter than a length of the guard ring in the second direction.

Yet some other embodiments of the present disclosure provide a semiconductor device including a first semiconductor structure comprising a first substrate and a first bonding insulation layer on the first substrate, a second semiconductor structure disposed on the first semiconductor structure, and a guard ring passing through the first and second semiconductor structures, wherein the second semiconductor structure includes a second bonding insulation layer bonded to the first bonding insulation layer, an alignment key disposed on the second bonding insulation layer, and an upper barrier structure disposed between the alignment key and the guard ring.

Yet some other embodiments of the present disclosure provide a semiconductor device including a chip region, a guard ring region surrounding the chip region, and a scribe lane region adjacent to the guard ring region, a guard ring disposed in the guard ring region and surrounding the chip region, an alignment key spaced apart from the guard ring inside the scribe lane region, and a barrier structure disposed between the guard ring and the alignment key, the barrier structure being connected to a substrate.

According to some embodiments of the present disclosure, a semiconductor device is provided that is capable of minimizing defects generated during the cutting process.

The advantageous effects of the embodiments of the present disclosure are not limited to those mentioned above, and other advantages not explicitly stated will be clearly understood by those skilled in the art from the detailed description and the claims.

### BRIEF DESCRIPTION OF THE DRAWINGS

The embodiments of the present disclosure will be more fully understood from the detailed description and accompanying drawings provided below, which are provided solely for illustrative purposes and do not limit the scope of the present disclosure.

FIG. 1 is a diagram illustrating a planar structure of a semiconductor device according to some embodiments of the present disclosure.

FIG. 2 is a diagram illustrating a cross-sectional structure taken along line I-I′ of FIG. 1.

FIGS. 3 and 4 are diagrams illustrating other cross-sectional structures taken along line I-I′ of FIG. 1.

FIG. 5 is a diagram illustrating another planar structure of a semiconductor device according to some embodiments of the present disclosure.

FIG. 6 is a diagram illustrating a cross-sectional structure taken along line II-II′ of FIG. 5.

FIGS. 7 through 15 are diagrams illustrating a method of manufacturing a semiconductor device according to some embodiments of the present disclosure.

FIGS. 16 through 19 are diagrams illustrating a method of manufacturing a semiconductor device according to some embodiments of the present disclosure.

### DETAILED DESCRIPTION

Hereinafter, some embodiments of the present disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, such details may be omitted. As used herein, terms such as “includes,” “has,” or “is composed of” in relation to a component may permit the inclusion of additional components unless terms like “only” are explicitly used. Additionally, unless the context clearly indicates otherwise, expressions in the singular, such as “a,” “an,” and “the” are intended to include their plural forms.

Labels such as “first," "second," "A," "B," "(a)," and "(b)" may be used to describe components of this disclosure. These labels are intended merely to distinguish one component from another, and are not intended to limit the nature, order, sequence, or number of the components.

Regarding the description of positional relationships between components, when two or more components are described as being "connected," "coupled," or "linked," it should be understood that they may be directly "connected," "coupled," or "linked," or may have an intervening component. Here, the intervening component may be included in one or more of the two or more components that are “connected,” “coupled,” or “linked” to each other.

When terms such as “after,” “next,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the present disclosure are described in detail with reference to the accompanying drawings.

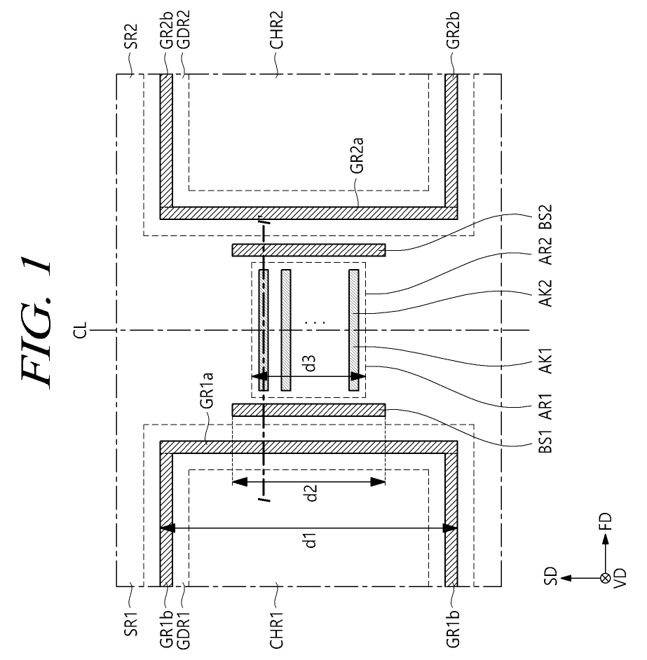

In FIG. 1 and the accompanying drawings, two directions along the top surface of a first substrate 300 are defined as a first direction FD and a second direction SD, respectively, and a direction protruding perpendicularly from the top surface of the first substrate 300 is defined as a third direction VD. The first direction FD and the second direction SD may be substantially perpendicular to each other. The third direction VD is perpendicular to both the first direction FD and the second direction SD. Hereinafter, the terms "perpendicular" or "perpendicular direction" will be used to mean substantially the same as the third direction VD. In the drawings, a direction indicated by an arrow and its opposite direction represent the same direction.

FIG. 1 is a diagram illustrating a planar structure of a semiconductor device according to some embodiments of the present disclosure. FIG. 1 may illustrate a state in which semiconductor devices are formed over a single wafer prior to being separated into individual chips.

Referring to FIG. 1, a first chip region CHR1 and a second chip region CHR2 are disposed spaced apart from each other. The first chip region CHR1 and the second chip region CHR2 may each represent a region where elements and wirings constituting one semiconductor device are disposed. For example, the elements and wirings disposed in the first chip region CHR1 may belong to a different semiconductor device from those disposed in the second chip region CHR2. For example, the elements and wirings of the first chip region CHR1 may belong to a first semiconductor device and the elements and wirings of the second chip region CHR2 may belong to a second semiconductor device.

A first guard ring region GDR1 may be disposed around the first chip region CHR1. The first guard ring region GDR1 may surround the first chip region CHR1. A second guard ring region GDR2 may be disposed around the second chip region CHR2. The second guard ring region GDR2 may surround the second chip region CHR2. The first guard ring region GDR1 and the second guard ring region GDR2 may each represent a region in which a guard ring is disposed.

A first scribe lane region SR1 is disposed around the first guard ring region GDR1. The first scribe lane region SR1 may surround the first guard ring region GDR1. A second scribe lane region SR2 is disposed around the second guard ring region GDR2. The second scribe lane region SR2 may surround the second guard ring region GDR2. The second scribe lane region SR2 may be continuous with the first scribe lane region SR1. The first scribe lane region SR1 and the second scribe lane region SR2 may be separated by a cutting line CL. According to some embodiments, the first and second scribe lane regions SR1 and SR2 may be separated from each other through a cutting process. The first and second scribe lane regions SR1 and SR2 may belong to different semiconductor devices.

According to some embodiments, the first chip region CHR1, the first guard ring region GDR1, and the first scribe lane region SR1 may be included in one semiconductor device (e.g., a first semiconductor device). The second chip region CHR2, the second guard ring region GDR2, and the second scribe lane region SR2 may be included in another semiconductor device (e.g., a second semiconductor device) different from the first semiconductor device.

Hereinafter, for the convenience of description, the semiconductor device according to some embodiments of the present disclosure will be referred to as the first semiconductor device.

A first guard ring GR1 is disposed in the first guard ring region GDR1. A second guard ring GR2 is disposed in the second guard ring region GDR2. The first guard ring GR1 may surround the first chip region CHR1. The second guard ring GR2 may surround the second chip region CHR2. The first guard ring GR1 may include a first horizontal guard portion GR1a and a second horizontal guard portion GR1b. The second guard ring GR2 may include a third horizontal guard portion GR2a and a fourth horizontal guard portion GR2b.

The first horizontal guard portion GR1a may extend in the second direction SD. The second horizontal guard portion GR1b may extend in the first direction FD. The first horizontal guard portion GR1a and the second horizontal guard portion GR1b may intersect each other. The first and second horizontal guard portions GR1a and GR1b may be perpendicular to each other, however, this is just one example configuration. For example, in some embodiments (not shown), the first and second horizontal guard portions GR1a and GR1b may intersect each other at a non-orthogonal angle.

A first key region AR1 may be located in the first scribe lane region SR1. A second key region AR2 may be located in the second scribe lane region SR2. The first key region AR1 and the second key region AR2 may each represent a region in which a key is disposed. According to some embodiments, various keys such as alignment keys, overlay keys, or combinations thereof may be disposed in the first and second key regions AR1 and AR2. For example, as illustrated in FIG. 1, a first alignment key AK1 may be disposed in the first key region AR1, and a second alignment key AK2 may be disposed in the second key region AR2. The first alignment key AK1 may be continuous with the second alignment key AK2. From a planar view as in FIG. 1, The first and second alignment keys AK1 and AK2 may form an elongated rectangular member extending in the first direction.

The first key region AR1 and the second key region AR2 may be disposed in part of the first scribe lane region SR1 and the second scribe lane region SR2, respectively. For example, a length d3 of the first key region AR1 in the second direction SD may be shorter than a length d1 of the first horizontal guard portion GR1a in the second direction SD.

The first alignment key AK1 and the second alignment key AK2 may be disposed in regions overlapping with the first horizontal guard portion GR1a and the third horizontal guard portion GR2a in the first direction FD. The first and second alignment keys AK1 and AK2 may be disposed in a portion of the first and second scribe lane regions SR1 and SR2.

A first barrier structure BS1 may be disposed between the first horizontal guard portion GR1a and the first alignment key AK1. A second barrier structure BS2 may be disposed between the third horizontal guard portion GR2a and the second alignment key AK2. According to some embodiments, a length d2 of the first barrier structure BS1 in the second direction SD may be longer than a length d3 of the first key region AR1 in the second direction SD. According to some embodiments, the length d2 of the first barrier structure BS1 in the second direction SD may be shorter than the length d1 of the first horizontal guard portion GR1a in the second direction SD.

Although FIG. 1 illustrates that the first barrier structure BS1 is disposed in the first scribe lane region SR1, it is not necessarily limited thereto. For example, the first barrier structure BS1 may also be disposed in the first guard ring region GDR1 or in the first key region AR1.

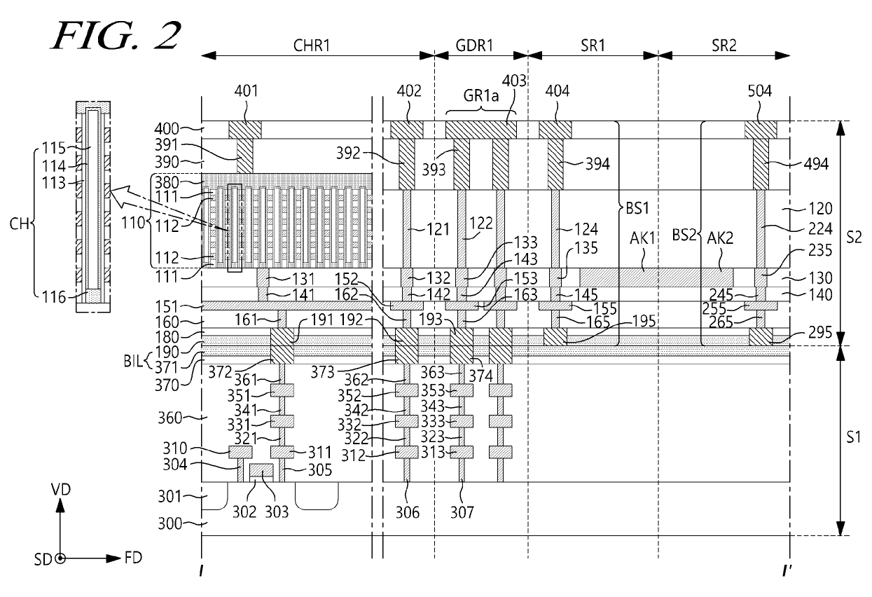

FIG. 2 is a diagram illustrating a cross-sectional structure taken along line I-I′ of FIG. 1.

Referring to FIG. 2, the first semiconductor device may include a first semiconductor structure S1 and a second semiconductor structure S2.

The first semiconductor structure S1 may include a first substrate 300, an element isolation layer 301, a gate insulation layer 302, a gate electrode 303, a source contact 304, a drain contact 305, a first lower contact 306, a second lower contact 307, a first lower wiring 310, a second lower wiring 311, a third lower wiring 312, a fourth lower wiring 313, a third lower contact 321, a fourth lower contact 322, a fifth lower contact 323, a fifth lower wiring 331, a sixth lower wiring 332, a seventh lower wiring 333, a sixth lower contact 341, a seventh lower contact 342, an eighth lower contact 343, an eighth lower wiring 351, a ninth lower wiring 352, a tenth lower wiring 353, a ninth lower contact 361, a tenth lower contact 362, an eleventh lower contact 363, a first insulation layer 360, a first interlayer insulation layer 370, a first bonding insulation layer 371, a first lower bonding pad 372, a second lower bonding pad 373, and a third lower bonding pad 374.

The source contact 304, the drain contact 305, the first lower contact 306, and the second lower contact 307 may be connected to the first substrate 300. The drain contact 305 may be connected to the first lower bonding pad 372 through wirings 311, 331, and 351, and contacts 321, 341, and 361. The first lower contact 306 may be connected to the second lower bonding pad 373 through wirings 312, 332, and 352, and contacts 322, 342, and 362. The second lower contact 307 may be connected to the third lower bonding pad 374 through wirings 313, 333, and 353, and contacts 323, 343, and 363.

A top surface of each of the first, second, and third lower bonding pads 372, 373, and 374 may be on a same plane or substantially a same plane as a top surface of the first bonding insulation layer 371.

The second semiconductor structure S2 may be disposed on the first semiconductor structure S1. The second semiconductor structure S2 may be bonded to the first semiconductor structure S1.

The second semiconductor structure S2 may include a stacked structure 110, a second insulation layer 120, a first upper contact 121, a second upper contact 122, a third upper contact 124, a second interlayer insulation layer 130, a fourth upper contact 131, a fifth upper contact 132, a sixth upper contact 133, a seventh upper contact 135, a first alignment key AK1, a third interlayer insulation layer 140, an eighth upper contact 141, a ninth upper contact 142, a tenth upper contact 143, an eleventh upper contact 145, a fourth interlayer insulation layer 160, a bit line 151, a first upper wiring 152, a second upper wiring 153, a third upper wiring 155, a twelfth upper contact 161, a thirteenth upper contact 162, a fourteenth upper contact 163, a fifteenth upper contact 165, a fifth interlayer insulation layer 180, a second bonding insulation layer 190, a first upper bonding pad 191, a second upper bonding pad 192, a third upper bonding pad 193, a fourth upper bonding pad 195, a third insulation layer 390, a sixteenth upper contact 391, a seventeenth upper contact 392, an eighteenth upper contact 393, a nineteenth upper contact 394, a sixth interlayer insulation layer 400, a fourth upper wiring 401, a fifth upper wiring 402, a sixth upper wiring 403, and a seventh upper wiring 404.

The stacked structure 110 may include an electrode layer 112, an insulation pattern 111, a source plate 380, and a channel structure CH. The channel structure CH may include a cell gate insulation layer 113, a channel pattern 114, a core insulation layer 115, and a drain pad 116.

The first barrier structure BS1 may include contacts 124, 135, 145, 165, and 394; wirings 155 and 404; and a fourth upper bonding pad 195. The second barrier structure BS2 may include contacts 224, 235, 245, 265, and 494; wirings 255 and 504; and a fifth upper bonding pad 295.

In the first chip region CHR1, the electrode layer 112 and the insulation pattern 111 may be alternately stacked. The channel structure CH may pass through the electrode layer 112 and the insulation pattern 111 to connect to the source plate 380. Although FIG. 2 illustrates the first semiconductor device including NAND memory cells, this is merely an example, and the first semiconductor device is not limited thereto.

The drain pad 116 of the channel structure CH may be connected to the bit line 151 through contacts 131 and 141. The bit line 151 may be connected to the second lower wiring 311 through bonding pads 191 and 372, contacts 161, 361, 341, and 321, and wirings 351 and 331.

The first horizontal guard portion GR1a may include contacts 122, 133, 143, 163, 363, 343, 323, and 307; wirings 403, 163, 353, 333, and 313; and bonding pads 193 and 374. The first horizontal guard portion GR1a may pass through the bonding insulation layer BIL and be connected to the first substrate 300. The first horizontal guard portion GR1a may pass through both the first semiconductor structure S1 and the second semiconductor structure S2. According to some embodiments, a ground voltage may be applied to the first horizontal guard portion GR1a.

Outside the first horizontal guard portion GR1a, the first barrier structure BS1 may be disposed. According to some embodiments, the first barrier structure BS1 may be included within the second semiconductor structure S2. According to some embodiments, a bottom surface of the first barrier structure BS1, that is, a bottom surface of the fourth upper bonding pad 195, may form substantially a same plane as a bottom surface of the second semiconductor structure S2. A top surface of the first barrier structure BS1, that is, a top surface of the seventh upper wiring 404, may form substantially a same plane as a top surface of the second semiconductor structure S2.

According to some embodiments, the first barrier structure BS1 may be located between the first horizontal guard portion GR1a and the first alignment key AK1. The first barrier structure BS1 may overlap with the first horizontal guard portion GR1a and the first alignment key AK1 in the first direction FD. The first alignment key AK1 may be disposed in the same layer as the seventh upper contact 135 included in the first barrier structure BS1. The first alignment key AK1 may be spaced apart from the first horizontal guard portion GR1a in the first direction FD. According to some embodiments, the first alignment key AK1 may be used to align the eleventh upper contact 145 with the seventh upper contact 135.

According to some embodiments, the first alignment key AK1 may overlap with the first barrier structure BS1. For example, the distance from the top surface of the first barrier structure BS1 to the first substrate 300 may be greater than the distance from the top surface of the first alignment key AK1 to the first substrate 300. Also, the distance from the bottom surface of the first barrier structure BS1 to the first substrate 300 may be less than the distance from the bottom surface of the first alignment key AK1 to the first substrate 300.

According to some embodiments, a bottom surface of the first barrier structure BS1, i.e., the bottom surface of the fourth upper bonding pad 195, may be on a same plane or substantially a same plane as a bottom surface of the second bonding insulation layer 190. According to some embodiments, a bottom surface of the first barrier structure BS1 may contact a top surface of the first bonding insulation layer 371.

According to some embodiments, the first barrier structure BS1 may be electrically floating. The first barrier structure BS1 may be physically and electrically separated from the first horizontal guard portion GR1a.

According to some embodiments, a cutting line may pass through an alignment region containing the first alignment key AK1. In such cases, when the semiconductor device is cut the direction of the cutting line may bend around the alignment region where the first alignment key AK1 is located which can lead to cracks or delamination, resulting in defects within the chip region. However, according to some embodiments of the present disclosure, since the first barrier structure BS1 is disposed between the first horizontal guard portion GR1a and the first alignment key AK1, the penetration of cracks or delamination into the first chip region CHR1 may be minimized.

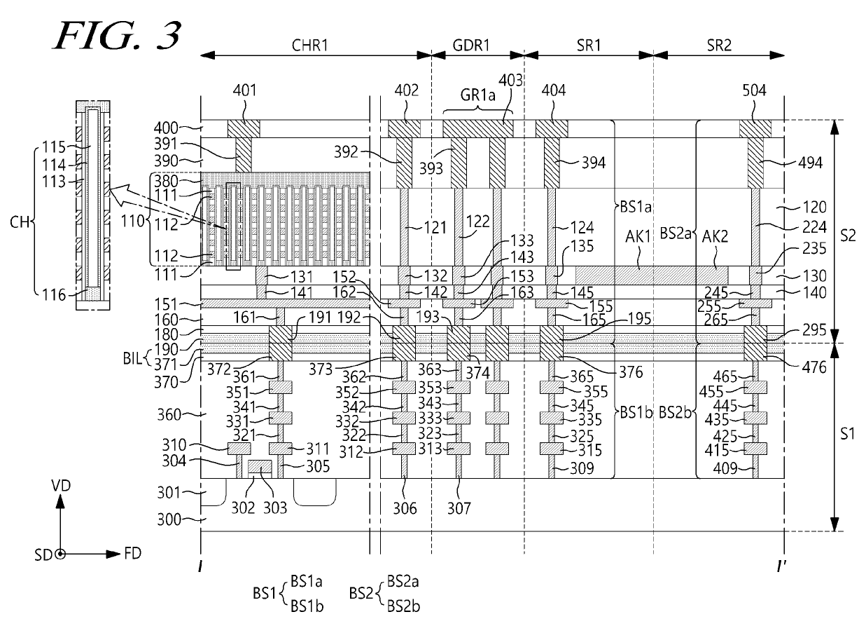

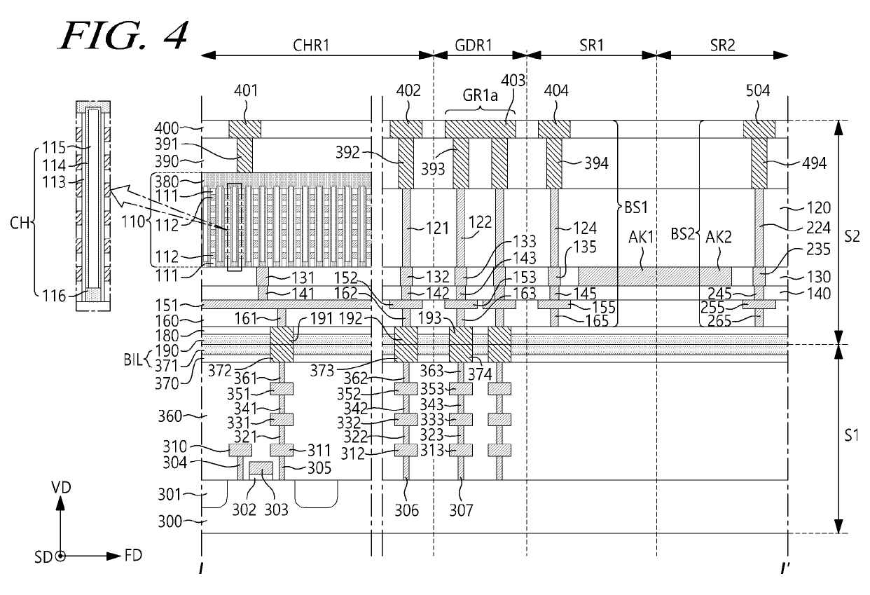

FIGS. 3 and 4 are cross-sectional views illustrating the section I-I′ of FIG. 1.

Referring to FIG. 3, the first semiconductor device may include first barrier structure BS1. The first barrier structure BS1 may include a first upper barrier structure BS1a and a first lower barrier structure BS1b. The first semiconductor structure S1 may include the first lower barrier structure BS1b. The second semiconductor structure S2 may include the first upper barrier structure BS1a. The second barrier structure BS2 may include a second upper barrier structure BS2a and a second lower barrier structure BS2b.

The first upper barrier structure BS1a may include contacts 394, 124, 135, 145, and 165; wirings 404 and 155; and a fourth upper bonding pad 195. The second upper barrier structure BS2a may include contacts 494, 224, 235, 245, and 265; wirings 504 and 255; and a fifth upper bonding pad 295. The first lower barrier structure BS1b may include contacts 309, 325, 345, and 365; wirings 315, 335, and 355; and a fourth lower bonding pad 376. The second lower barrier structure BS2b may include contacts 409, 425, 445, and 465; wirings 415, 435, and 455; and a fifth lower bonding pad 476.

The first upper barrier structure BS1a may be directly connected to the first lower barrier structure BS1b. For example, a bottom surface of the first upper barrier structure BS1a, i.e., a bottom surface of the fourth upper bonding pad 195, may contact a top surface of the first lower barrier structure BS1b, i.e., a top surface of the fourth lower bonding pad 376. The first barrier structure BS1 may pass through the bonding insulation layer BIL and be connected to the first substrate 300.

The first barrier structure BS1 may be disposed between the first alignment key AK1 and the first horizontal guard portion GR1a. The first barrier structure BS1 may overlap with the first horizontal guard portion GR1a and the first alignment key AK1 in the first direction FD. The first alignment key AK1 may be spaced apart from the first horizontal guard portion GR1a in the first direction FD.

According to some embodiments, the first barrier structure BS1 may be electrically floating. The first barrier structure BS1 may be physically and electrically separated from the first horizontal guard portion GR1a.

According to some embodiments, the first barrier structure BS1 may be formed together with the first horizontal guard portion GR1a. According to some embodiments, the first barrier structure BS1 may perform a function similar to that of the first horizontal guard portion GR1a. For example, the first barrier structure BS1 may block moisture entering from outside the first chip region CHR1.

According to some embodiments, the first barrier structure BS1 may fully overlap with the first horizontal guard portion GR1a in the first direction FD. When the first barrier structure BS1 is disposed to fully overlap with the first horizontal guard portion GR1a in the first direction FD, penetration of cracks or delamination generated during the cutting process into the chip region may be more effectively prevented.

Referring to FIG. 4, the first semiconductor device may include the first barrier structure BS1. The first barrier structure BS1 may be included in the second semiconductor structure S2. The first barrier structure BS1 may include contacts 394, 124, 135, 145, and 165, and wirings 404 and 155.

According to some embodiments, the first barrier structure BS1 may be disposed on the fifth interlayer insulation layer 180. The first barrier structure BS1 may be spaced apart from the bonding insulation layer BIL. A bottom surface of the first barrier structure BS1, i.e., a bottom surface of the fifteenth upper contact 165, may form substantially a same plane as a bottom surface of the fourth interlayer insulation layer 160. A top surface of the first barrier structure BS1, i.e., a top surface of the seventh upper wiring 404, may form substantially a same plane as a top surface of the second semiconductor structure S2.

According to some embodiments, the first barrier structure BS1 may be disposed between the first horizontal guard portion GR1a and the first alignment key AK1. The first barrier structure BS1 may overlap with the first horizontal guard portion GR1a and the first alignment key AK1 in the first direction FD.

According to some embodiments, the first alignment key AK1 may be overlap with the first barrier structure BS1. For example, the distance from the top surface of the first barrier structure BS1 to the first substrate 300 may be greater than the distance from the top surface of the first alignment key AK1 to the first substrate 300, and the distance from the bottom surface of the first barrier structure BS1 to the first substrate 300 may be less than the distance from the bottom surface of the first alignment key AK1 to the first substrate 300.

According to some embodiments, the first barrier structure BS1 may be electrically floating. The first barrier structure BS1 may be physically and electrically separated from the first horizontal guard portion GR1a.

According to some embodiments, the first barrier structure BS1 may be spaced apart from the bonding insulation layer BIL. For example, the first barrier structure BS1 may not include the fourth upper bonding pad 195 described with reference to FIG. 2. In this case, since a contact area between the first bonding insulation layer 371 and the second bonding insulation layer 190 becomes larger, the first semiconductor structure S1 and the second semiconductor structure S2 may be bonded more effectively.

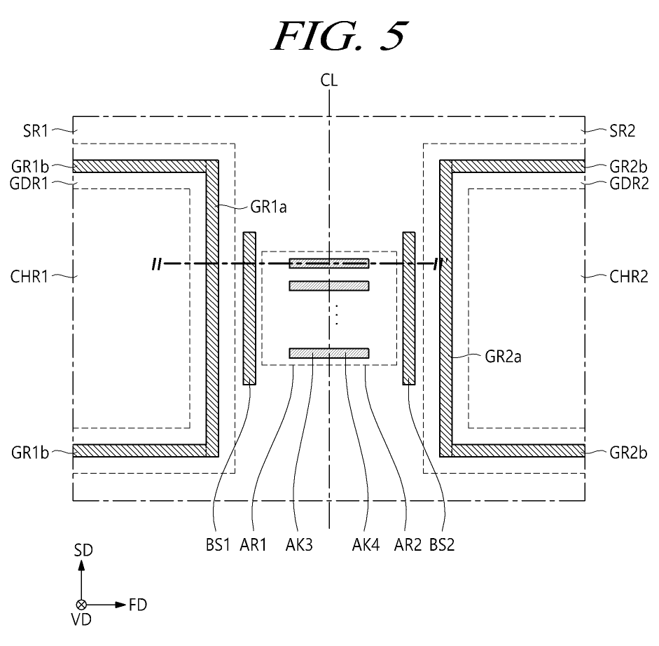

FIG. 5 is a plan view illustrating another a semiconductor device according to some embodiments of the present disclosure.

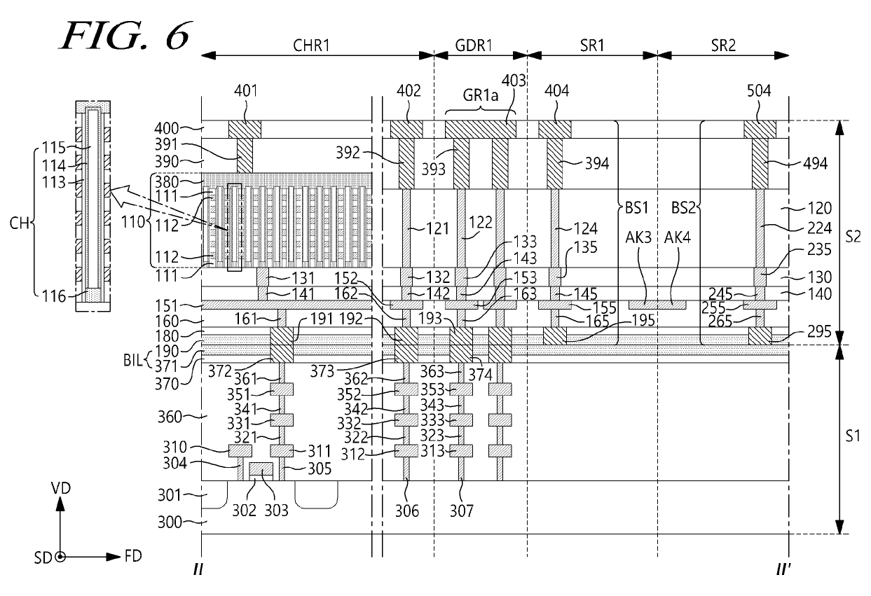

FIG. 6 is a cross-sectional view illustrating section II–II′ of FIG. 5.

The first semiconductor device illustrated in FIGS. 5 and 6 may include a third alignment key AK3. Except for including the third alignment key AK3, the first semiconductor device illustrated in FIGS. 5 and 6 is substantially the same as the first semiconductor device described with reference to FIGS. 1 and 2, and thus, redundant description is omitted.

Referring to FIGS. 5 and 6, the first barrier structure BS1 may overlap with the third alignment key AK3 in the first direction FD. A third upper wiring 155 included in the first barrier structure BS1 may be disposed in the same layer as the third alignment key AK3. According to some embodiments, the third alignment key AK3 may be a key used to align a fifteenth upper contact 165 with the third upper wiring 155.

According to some embodiments, the third alignment key AK3 may overlap with the first barrier structure BS1. For example, a distance from the top surface of the first barrier structure BS1 to the first substrate 300 may be greater than a distance from the top surface of the third alignment key AK3 to the first substrate 300, and a distance from the bottom surface of the first barrier structure BS1 to the first substrate 300 may be less than a distance from the bottom surface of the third alignment key AK3 to the first substrate 300.

For the sake of description, the first alignment key (AK1) and the third alignment key (AK3) are illustrated in FIGS. 2 and 6, respectively. Both AK1 and AK3 may be included within the first semiconductor device. Additionally, the first semiconductor device may include various other types of alignment keys beyond those mentioned above.

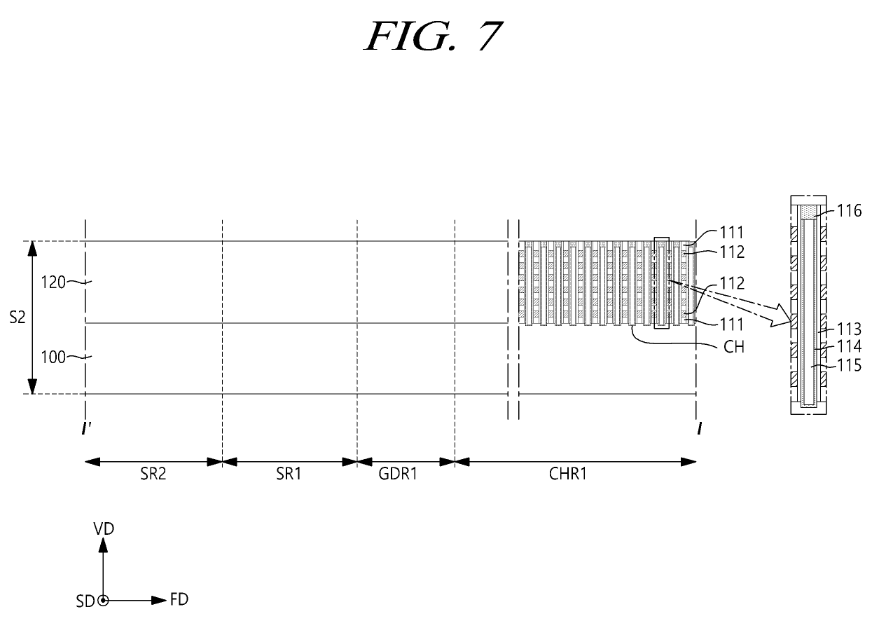

FIGS. 7 to 15 illustrate a method of manufacturing the semiconductor device according to some embodiments of the present disclosure.

Referring to FIG. 7, a second insulation layer 120, a channel structure CH, an electrode layer 112, and an insulation pattern 111 may be formed over a second substrate 100.

The second substrate 100 may include a semiconductor substrate such as a silicon wafer or a silicon-on-insulator (SOI) wafer. The second substrate 100 may include a Group III–V semiconductor substrate, such as a compound semiconductor substrate like gallium arsenide (GaAs). The second substrate 100 may include single-crystal silicon, polysilicon, amorphous silicon, single-crystal silicon germanium, polycrystalline silicon germanium, carbon-doped silicon, or combinations thereof.

The channel structure CH may pass through the electrode layer 112 and the insulation pattern 111 and may be connected to the second substrate 100. The channel structure CH may include a cell gate insulation layer 113, a channel pattern 114, a core insulation layer 115, and the drain pad 116.

The electrode layer 112 and the drain pad 116 may include a conductive material such as metal, metal oxide, metal nitride, metal silicide, polysilicon, conductive carbon, or a combination thereof.

The insulation pattern 111, the cell gate insulation layer 113, the core insulation layer 115, and the second insulation layer 120 may include silicon oxide, silicon nitride, silicon oxynitride, high-k dielectric material, or a combination thereof. In the drawings below, insulation layers, interlayer insulation layers, and bonding insulation layers may each include silicon oxide, silicon nitride, silicon oxynitride, high-k dielectric material, or a combination thereof.

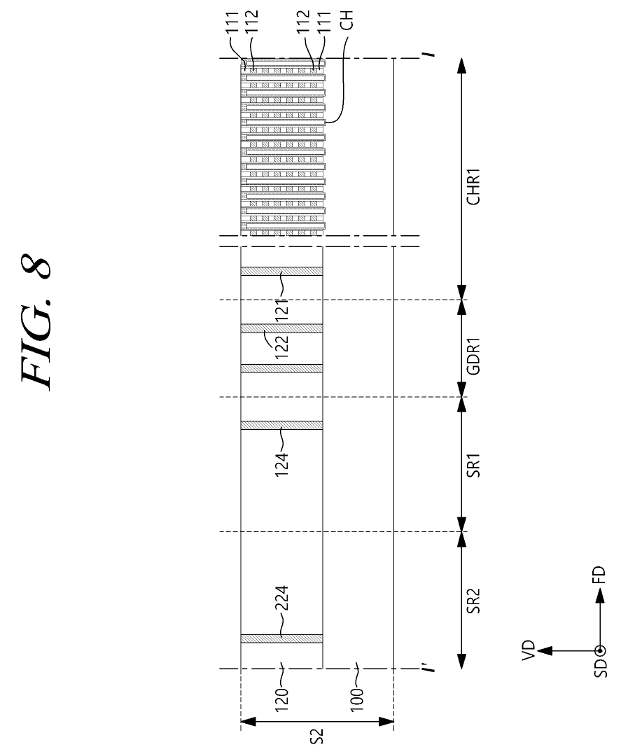

Referring to FIG. 8, the first upper contact 121, the second upper contact 122, the third upper contact 124, and a twentieth upper contact 224 may be formed over the second substrate 100. The first upper contact 121, the second upper contact 122, the third upper contact 124, and the twentieth upper contact 224 may pass through the second insulation layer 120 and may contact the second substrate 100.

The first upper contact 121, the second upper contact 122, the third upper contact 124, and the twentieth upper contact 224 may include a conductive material such as metal, metal oxide, metal nitride, metal silicide, polysilicon, conductive carbon, or a combination thereof. In the drawings below, the contacts and wirings may each include a conductive material such as metal, metal oxide, metal nitride, metal silicide, polysilicon, conductive carbon, or a combination thereof.

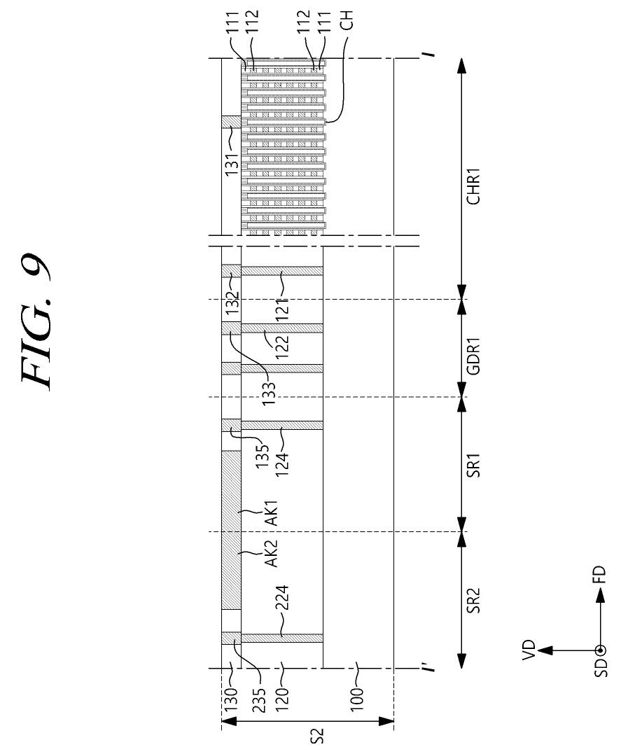

Referring to FIG. 9, the second interlayer insulation layer 130 may be formed over the channel structure CH, the insulation pattern 111, the second insulation layer 120, the first upper contact 121, the second upper contact 122, the third upper contact 124, and the twentieth upper contact 224.

A fourth upper contact 131 connected to the channel structure CH may be formed. Fifth, sixth, seventh, and twenty-first upper contacts 132, 133, 135, and 235, respectively, may be formed and may be connected respectively to the first, second, third, and twentieth upper contacts 121, 122, 124, and 224.

The first alignment key AK1 and the second alignment key AK2 may be formed in the same layer as the seventh upper contact 135. A top surface of the first alignment key AK1 may form substantially a same plane as a top surface of the seventh upper contact 135. A bottom surface of the first alignment key AK1 may form substantially a same plane as a bottom surface of the seventh upper contact 135.

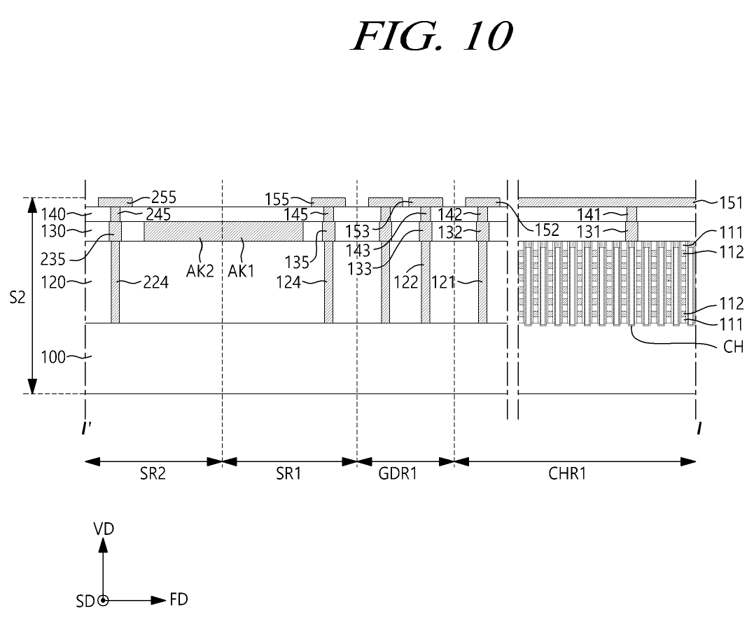

Referring to FIG. 10, the third interlayer insulation layer 140 may be formed over the fourth upper contact 131, the fifth upper contact 132, the sixth upper contact 133, the seventh upper contact 135, and the twenty-first upper contact 235. Eighth, ninth, tenth, eleventh, and twenty-second upper contacts 141, 142, 143, 145, and 245 may be respectively formed to connect respectively to the fourth, fifth, sixth, seventh, and twenty-first upper contacts 131, 132, 133, 135, and 235. A bit line 151, a first upper wiring 152, a second upper wiring 153, a third upper wiring 155, and an eighth upper wiring 255 may be formed to be connected respectively to the eighth, ninth, tenth, eleventh, and twenty-second upper contacts 141, 142, 143, 145, and 245.

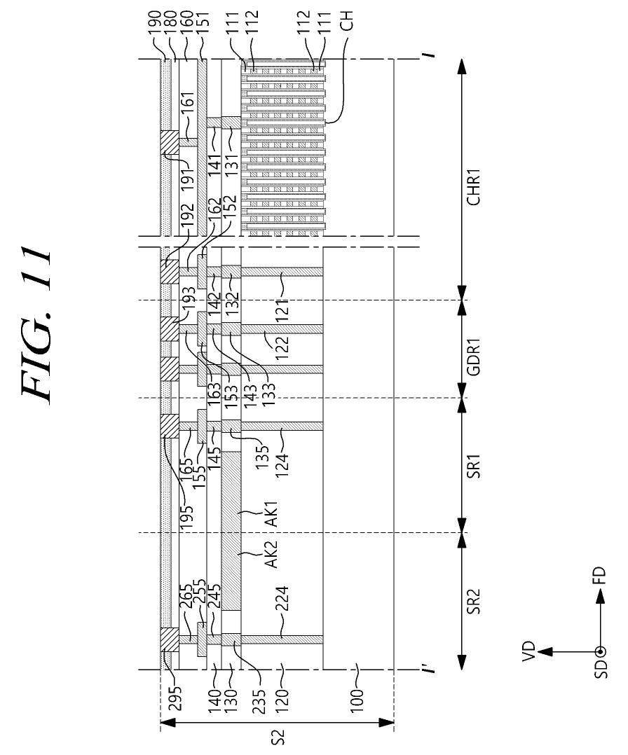

Referring to FIG. 11, a fourth interlayer insulation layer 160 may be formed over the bit line 151, the first upper wiring 152, the second upper wiring 153, the third upper wiring 155, and the eighth upper wiring 255. Twelfth, thirteenth, fourteenth, fifteenth, and twenty-third upper contacts 161, 162, 163, 165, and 265 may be formed to connect respectively to the bit line 151, the first upper wiring 152, the second upper wiring 153, the third upper wiring 155, and the eighth upper wiring 255. The fifth interlayer insulation layer 180 may be formed over the twelfth, thirteenth, fourteenth, fifteenth, and twenty-third upper contacts 161, 162, 163, 165, and 265. A second bonding insulation layer 190 may be formed over the fifth interlayer insulation layer 180.

First through fifth upper bonding pads 191, 192, 193, 195, and 295 may be formed to respectively connect to the twelfth through fifteenth and twenty-third upper contacts 161, 162, 163, 165, and 265. The top surfaces of the first through fifth upper bonding pads 191 to 295 may form substantially a same plane as a top surface of the second bonding insulation layer 190.

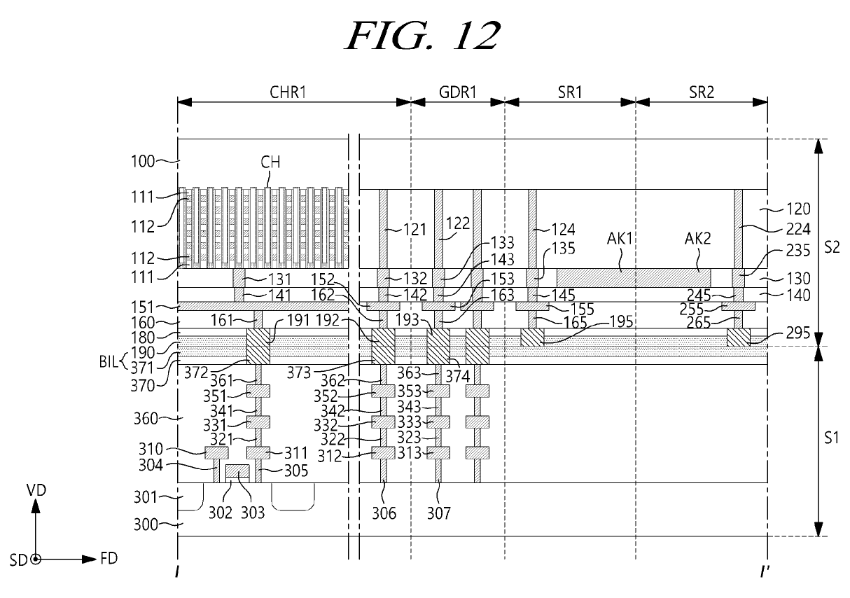

Referring to FIG. 12, the second semiconductor structure S2 may be bonded onto the first semiconductor structure S1. For example, a top surface of the first bonding insulation layer 371 may be bonded to a bottom surface of the second bonding insulation layer 190. The bonding between the first semiconductor structure S1 and the second semiconductor structure S2 may include bonding between insulation layers.

The first semiconductor structure S1 may include a first substrate 300, an element isolation layer 301, a gate insulation layer 302, a gate electrode 303, a first insulation layer 360, contacts 304, 305, 306, 307, 321, 322, 323, 341, 342, 343, 361, 362, 363, wirings 310, 311, 312, 313, 331, 332, 333, 351, 352, 353, a first interlayer insulation layer 370, a first bonding insulation layer 371, and lower bonding pads 372, 373, 374.

The first substrate 300 may include a semiconductor substrate such as a silicon wafer or a silicon-on-insulator (SOI) wafer. The first substrate 300 may include a Group III–V semiconductor substrate, such as a compound semiconductor substrate like GaAs. The first substrate 300 may include single-crystal silicon, polysilicon, amorphous silicon, single-crystal silicon germanium, polycrystalline silicon germanium, carbon-doped silicon, or a combination thereof.

The element isolation layer 301, the gate insulation layer 302, the first insulation layer 360, the first interlayer insulation layer 370, and the first bonding insulation layer 371 may include silicon oxide, silicon nitride, silicon oxynitride, high-k dielectric material, or a combination thereof. The gate electrode 303, the contacts 304, 305, 306, 307, 321, 322, 323, 341, 342, 343, 361, 362, 363, the wirings 310, 311, 312, 313, 331, 332, 333, 351, 352, 353, and the lower bonding pads 372, 373, 374 may include a conductive material such as metal, metal oxide, metal nitride, metal silicide, polysilicon, conductive carbon, or a combination thereof.

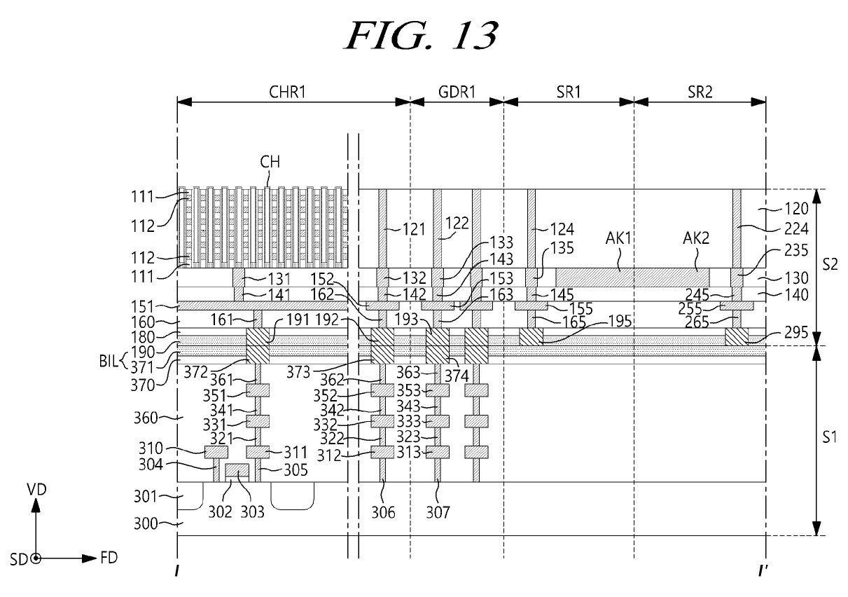

Referring to FIG. 13, the second substrate 100 may be removed, for example, by a process including a grinding process, a chemical mechanical polishing (CMP) process, a laser lift-off (LLO) process, or a combination thereof.

As the second substrate 100 is removed, top surfaces of the channel structure CH, the second insulation layer 120, the first upper contact 121, the second upper contact 122, the third upper contact 124, and the twentieth upper contact 224 may be exposed.

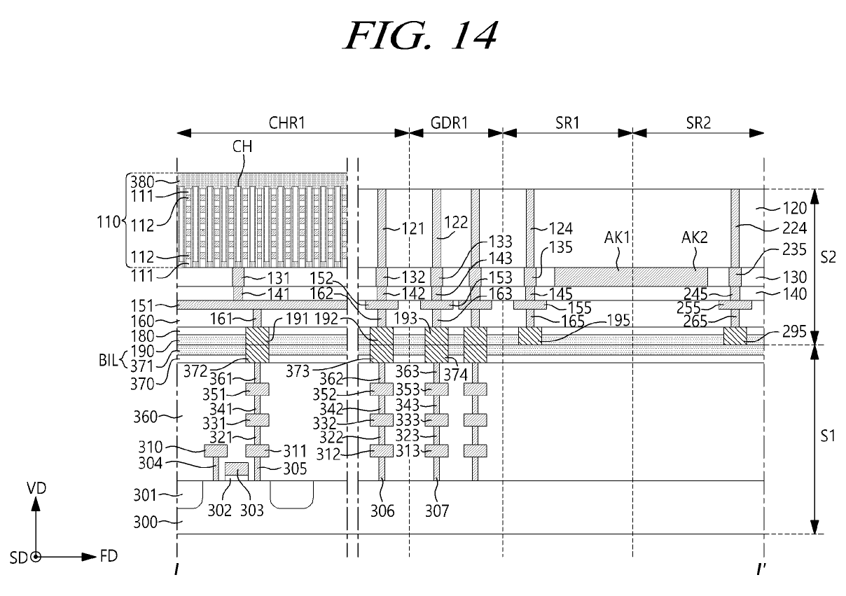

Referring to FIG. 14, a source plate 380 may be formed over the channel structure CH. The source plate 380 may be formed within the first chip region CHR1. The source plate 380 may cover a top surface of the channel structure CH. The source plate 380 may include polysilicon.

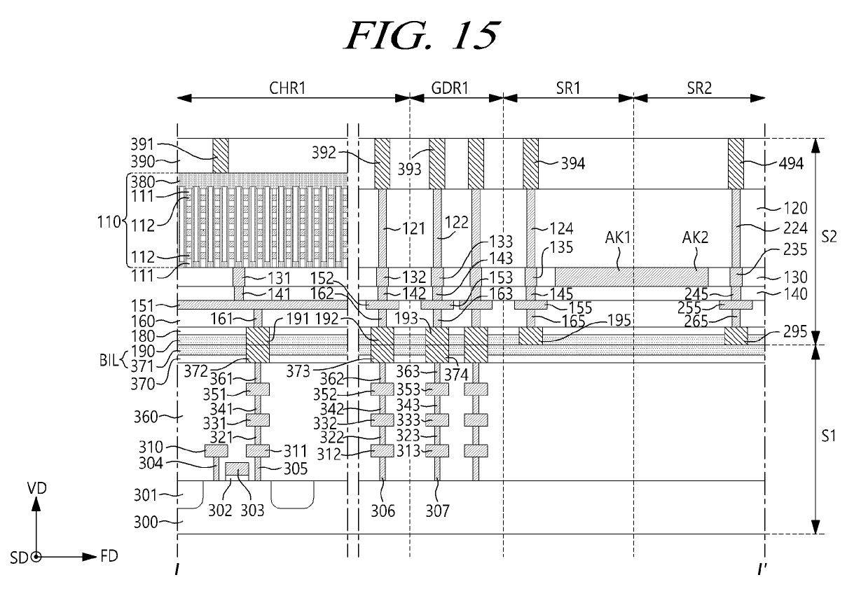

Referring to FIG. 15, a third insulation layer 390 may be formed over the source plate 380 and the second insulation layer 120. A sixteenth upper contact 391, which passes through the third insulation layer 390 and connects to the source plate 380, may be formed. Seventeenth, eighteenth, nineteenth, and twenty-fourth upper contacts 392, 393, 394, and 494 may be formed to respectively connect to the first, second, third, and twentieth upper contacts 121, 122, 124, and 224 through the third insulation layer 390.

Referring again to FIG. 2, a sixth interlayer insulation layer 400 may be formed over the third insulation layer 390. Fourth, fifth, sixth, seventh, and ninth upper wirings 401, 402, 403, 404, and 504 may be formed to respectively connect to the sixteenth, seventeenth, eighteenth, nineteenth, and twenty-fourth upper contacts 391, 392, 393, 394, and 494 through the sixth interlayer insulation layer 400.

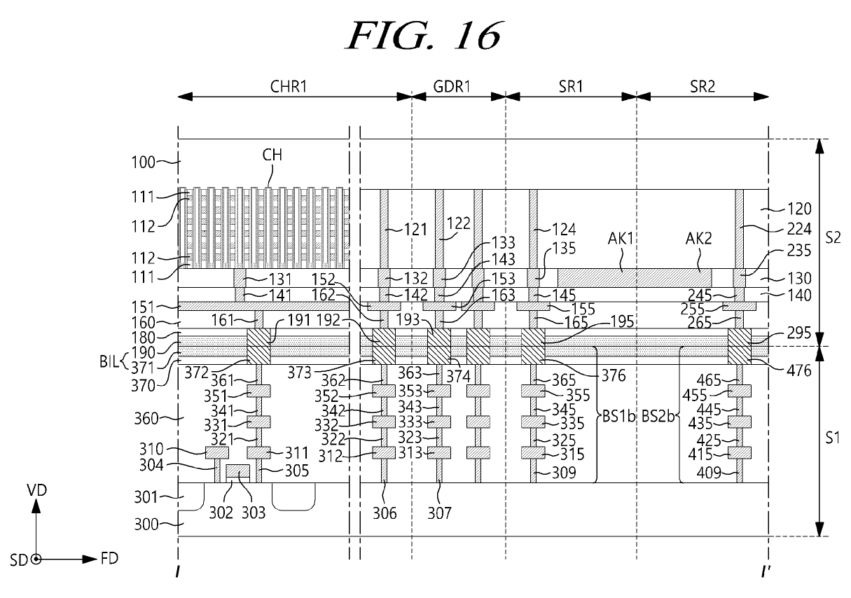

FIGS. 16 through 19 illustrate other methods for manufacturing the semiconductor device according to some embodiments of the present disclosure.

The first semiconductor device shown in FIG. 16 may be formed using the same method as the method of manufacturing the first semiconductor device described with reference to FIGS. 7 through 11.

Referring to FIG. 16, the second semiconductor structure S2 may be bonded onto the first semiconductor structure S1.

The first semiconductor structure S1 may include a first lower barrier structure BS1b and a second lower barrier structure BS2b.

The first lower barrier structure BS1b may be directly connected to the first substrate 300. The first lower barrier structure BS1b may be directly connected to the second semiconductor structure S2. The first lower barrier structure BS1b may be directly connected to the fourth upper bonding pad 195.

The processes following the bonding of the second semiconductor structure S2 to the first semiconductor structure S1 may proceed in the same manner as the method of manufacturing the first semiconductor device described with reference to FIGS. 3 and 13 through 15.

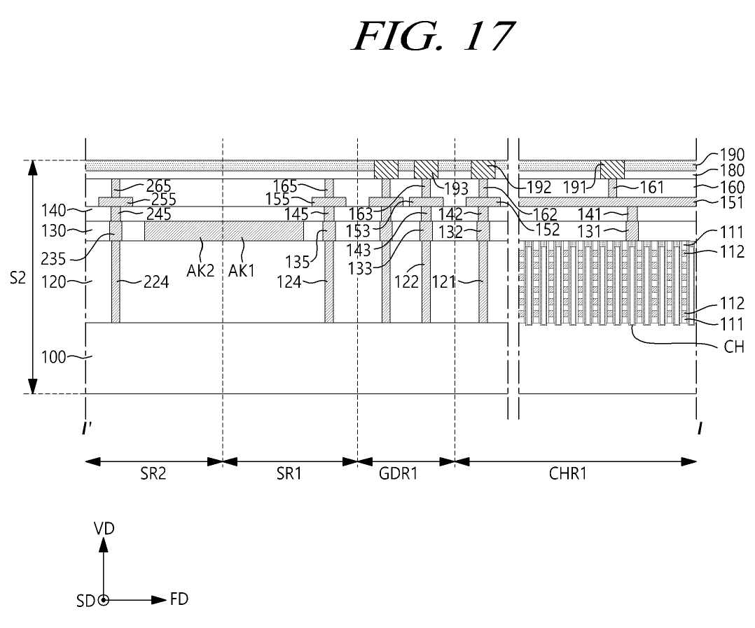

The first semiconductor device shown in FIG. 17 may be formed using the same method as the method of manufacturing the first semiconductor device described with reference to FIGS. 7 through 10.

Referring to FIG. 17, a fourth interlayer insulation layer 160 may be formed over the bit line 151, the first upper wiring 152, the second upper wiring 153, the third upper wiring 155, and the eighth upper wiring 255. Twelfth through fifteenth and twenty-third upper contacts 161, 162, 163, 165, and 265, respectively connected to the bit line 151 and the first through third and eighth upper wirings 152, 153, 155, and 255, may be formed. The fifth interlayer insulation layer 180 may be formed over the twelfth through fifteenth and twenty-third upper contacts 161, 162, 163, 165, and 265. A second bonding insulation layer 190 may be formed over the fifth interlayer insulation layer 180.

First through third upper bonding pads 191, 192, and 193 may be formed to respectively connect to the twelfth through fourteenth upper contacts 161, 162, and 163. Top surfaces of the first through third upper bonding pads 191 to 193 may form substantially a same plane as a top surface of the second bonding insulation layer 190.

The subsequent processes may proceed in the same manner as the method of manufacturing the first semiconductor device described with reference to FIGS. 4 and 12 through 15.

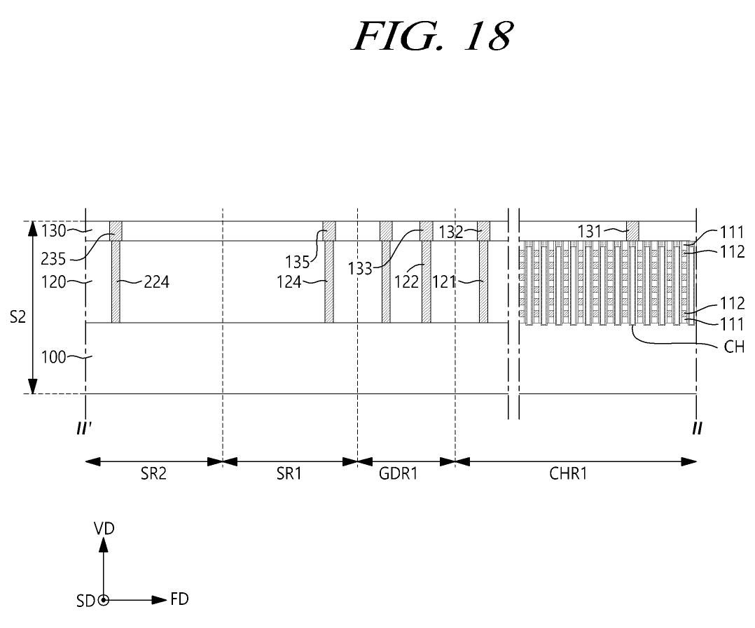

The first semiconductor device shown in FIG. 18 may be formed using the same method as the method of manufacturing the first semiconductor device described with reference to FIGS. 7 and 8.

Referring to FIG. 18, the second interlayer insulation layer 130 may be formed over the channel structure CH, the insulation pattern 111, the second insulation layer 120, the first upper contact 121, the second upper contact 122, the third upper contact 124, and the twentieth upper contact 224.

A fourth upper contact 131 connected to the channel structure CH may be formed. Fifth through seventh and twenty-first upper contacts 132, 133, 135, and 235 may be formed to respectively connect to the first through third and twentieth upper contacts 121, 122, 124, and 224.

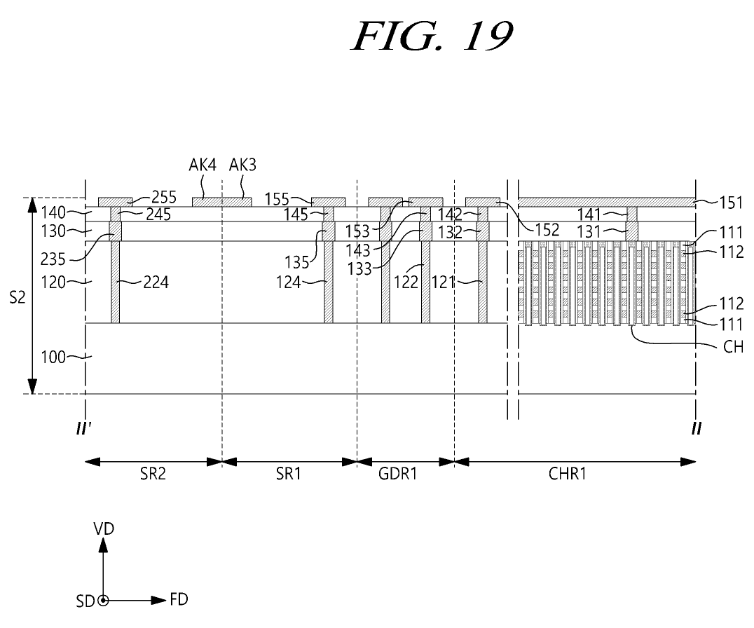

Referring to FIG. 19, the third interlayer insulation layer 140 may be formed over the fourth through seventh and twenty-first upper contacts 131, 132, 133, 135, and 235. Eighth through eleventh and twenty-second upper contacts 141, 142, 143, 145, and 245 may be formed to respectively connect to the fourth through seventh and twenty-first upper contacts 131, 132, 133, 135, and 235. Bit line 151, first upper wiring 152, second upper wiring 153, third upper wiring 155, and eighth upper wiring 255, which are respectively connected to the eighth through eleventh and twenty-second upper contacts 141, 142, 143, 145, and 245, may be formed.

Third and fourth alignment keys AK3 and AK4 may be formed over the third interlayer insulation layer 140. The third and fourth alignment keys AK3 and AKb may be formed over the same layer as the third upper wiring 155. A top surface of the third alignment key AK3 may form substantially a same plane as a top surface of the third upper wiring 155. A bottom surface of the third alignment key AK3 may form substantially a same plane as a bottom surface of the third upper wiring 155.

The subsequent processes may proceed in the same manner as the method of manufacturing the first semiconductor device described with reference to FIGS. 6 and 11 through 15.

The above description provides an illustrative description of the embodiments of the present disclosure. Accordingly, a person of ordinary skill in the art can make various modifications and variations without departing from the essential characteristics of the present disclosure. In addition, the embodiments disclosed in the present disclosure are not intended to limit the scope of the present disclosure but rather to describe features of the embodiments. Therefore, the scope of the present disclosure should not be limited by the particular embodiments disclosed herein. Furthermore, the embodiments may be combined to form additional embodiments.

What is claimed is:

1. A semiconductor device comprising:
a substrate including a chip region, a guard ring region disposed around the chip region, and a scribe lane region disposed around the guard ring region;
a guard ring disposed in the guard ring region, surrounding the chip region, and including a first horizontal guard portion and a second horizontal guard portion intersecting with the first horizontal guard portion;
an alignment key disposed in an alignment region inside the scribe lane region, the alignment key being spaced apart from the first horizontal guard portion in a first direction in which the second horizontal guard portion extends; and
a barrier structure disposed between the first horizontal guard portion and the alignment key.

2. The semiconductor device according to claim 1,
wherein, in a second direction intersecting the first direction, a length of the barrier structure is shorter than a length of the first horizontal guard portion in the second direction.

3. The semiconductor device according to claim 1,
wherein, in a second direction intersecting the first direction, a length of the barrier structure is longer than a length, in the second direction, of a region in which the alignment key is disposed.

4. The semiconductor device according to claim 1,
wherein a distance from the substrate to a top surface of the alignment key is less than a distance from the substrate to a top surface of the barrier structure, and
wherein a distance from the substrate to a bottom surface of the alignment key is greater than a distance from the substrate to a bottom surface of the barrier structure.

5. The semiconductor device according to claim 1,
further comprising a bonding insulation layer on the substrate,
wherein the bonding insulation layer includes a first bonding insulation layer and a second bonding insulation layer disposed on the first bonding insulation layer, and
wherein a bottom surface of the barrier structure forms a same plane as a bottom surface of the second bonding insulation layer.

6. The semiconductor device according to claim 1,
wherein the barrier structure contacts the substrate.

7. The semiconductor device according to claim 1,
further comprising a bonding insulation layer on the substrate,
wherein the barrier structure is disposed on the bonding insulation layer.

8. The semiconductor device according to claim 7,
wherein the barrier structure is spaced apart from the bonding insulation layer.

9. The semiconductor device according to claim 1,
wherein the barrier structure is electrically floating.

10. A semiconductor device comprising:
a substrate including a chip region, a guard ring region disposed around the chip region, and a scribe lane region disposed around the guard ring region;
a guard ring disposed in the guard ring region and surrounding the chip region;
an alignment key disposed in the scribe lane region, spaced apart from the guard ring in a first direction in which the guard ring extends; and
a barrier structure disposed between the guard ring and the alignment key and having a length in a second direction intersecting the first direction, the length being shorter than a length of the guard ring in the second direction.

11. The semiconductor device according to claim 10,
wherein the barrier structure overlaps with the alignment key in the first direction.

12. The semiconductor device according to claim 10,
wherein the length of the barrier structure in the second direction is longer than a length, in the second direction, of a region in which the alignment key is disposed in the second direction.

13. The semiconductor device according to claim 10,
wherein a distance from the substrate to a top surface of the alignment key is less than a distance from the substrate to a top surface of the barrier structure, and
wherein a distance from the substrate to a bottom surface of the alignment key is greater than a distance from the substrate to a bottom surface of the barrier structure.

14. The semiconductor device according to claim 10,
further comprising a bonding insulation layer on the substrate,
wherein the bonding insulation layer includes a first bonding insulation layer and a second bonding insulation layer disposed on the first bonding insulation layer, and
wherein a bottom surface of the barrier structure forms aa same plane as a bottom surface of the second bonding insulation layer.

15. The semiconductor device according to claim 10,
further comprising a bonding insulation layer on the substrate,
wherein the barrier structure is disposed on the bonding insulation layer.

16. The semiconductor device according to claim 10,
wherein the barrier structure is electrically floating.

17. A semiconductor device comprising:
a first semiconductor structure including a first substrate and a first bonding insulation layer on the first substrate;
a second semiconductor structure disposed on the first semiconductor structure; and
a guard ring passing through the first semiconductor structure and the second semiconductor structure,
wherein the second semiconductor structure comprises:
a second bonding insulation layer bonded to the first bonding insulation layer;
an alignment key disposed on the second bonding insulation layer; and
an upper barrier structure disposed between the alignment key and the guard ring.

18. The semiconductor device according to claim 17,
wherein a bottom surface of the upper barrier structure forms aa same plane as a bottom surface of the second bonding insulation layer.

19. The semiconductor device according to claim 17,
wherein the first semiconductor structure further comprises a lower barrier structure connected to the upper barrier structure, and
wherein the lower barrier structure contacts the substrate.

20. The semiconductor device according to claim 17,
wherein the upper barrier structure is spaced apart from the second bonding insulation layer.
